(19) United States
(12) Patent Application Publication
(10) Pub. No.: US 2011/0304050 A1
(43) Pub. Date: Dec. 15, 2011

(54) SEMICONDUCTOR APPARATUS

(75) Inventors: Takashi IMOTO, Mie-ken (JP); Yusuke AKADA, Mie-ken (JP); Masaji RI, Kanagawa-ken (JP); Tetsuya SATO, Mie-ken (JP)

(73) Assignee: KABUSHIKI KAISHA TOSHIBA, Tokyo (JP)

(21) Appl. No.: 13/031,856

(22) Filed: Feb. 22, 2011

(30) Foreign Application Priority Data
Jun. 9, 2010 (JP) 2010-132108

(51) Int. Cl. H01L 23/48

(52) U.S. Cl. 257/770; 257/782; 257/E23.01

(57) ABSTRACT

According to one embodiment, a semiconductor apparatus includes a substrate, a first semiconductor device, a circuit pattern, and a potential unit. The substrate includes a first insulating layer and a second insulating layer stacked with the first insulating layer. The first semiconductor device is provided on a side of the first insulating layer opposite to the second insulating layer side. The circuit pattern is provided between the first insulating layer and the second insulating layer. The potential unit is provided between the first insulating layer and the second insulating layer. The potential unit is connected to ground or a power source.

### CROSS-REFERENCE TO RELATED APPLICATIONS

This application is based upon and claims the benefit of priority from the prior Japanese Patent Application No. 2010-132108, filed on Jun. 9, 2010; the entire contents of which are incorporated herein by reference.

### FIELD

Embodiments described herein relate generally to a semiconductor apparatus.

### BACKGROUND

In recent years, effects of metal contamination on semiconductor devices have become problematic. Further, metal contamination in the so-called back-end processes such as the packaging process also has become problematic.

Therefore, there is a need to develop technology to suppress the effects of metal contamination.

### BRIEF DESCRIPTION OF THE DRAWINGS

FIG. 1 is a schematic partially enlarged view illustrating a semiconductor apparatus according to an embodiment;

FIG. 2A is a schematic view illustrating a potential unit; and FIG. 2B is an enlarged schematic view of portion C of FIG. 2A;

FIG. 3A is a schematic cross-sectional view illustrating the case where surface roughening is performed; and FIG. 3B is a schematic cross-sectional view illustrating the case where mirror finishing is performed;

FIG. 4A is a schematic view illustrating a potential unit according to another embodiment; and FIG. 4B is an enlarged schematic view of portion C1 of FIG. 4A;

FIG. 5 is a schematic view illustrating a potential unit according to a comparative example; and

FIGS. 6A to 6E schematically illustrate fail bit maps.

### DETAILED DESCRIPTION

In general, according to one embodiment, a semiconductor apparatus includes a substrate, a first semiconductor device, a circuit pattern, and a potential unit. The substrate includes a first insulating layer and a second insulating layer stacked with the first insulating layer. The first semiconductor device is provided on a side of the first insulating layer opposite to the second insulating layer side. The circuit pattern is provided between the first insulating layer and the second insulating layer. The potential unit is provided between the first insulating layer and the second insulating layer. The potential unit is connected to ground or a power source.

Before illustrating the semiconductor apparatus according to this embodiment, suppression of metal contamination of the semiconductor apparatus will be described.

Effects on yields due to trace metal contamination are increasing as semiconductor devices (semiconductor chips) are downscaled. In recent years, metal contamination control has become more complex due to the progress of semiconductor devices with thinner films and more layers as the semiconductor devices are made in three dimensions and with higher integration.

Therefore, currently, the metal removal process time is set to be long enough to reliably remove the metal contamination because it is necessary to control the front surface contamination, the back surface contamination, and the side surface contamination in the wafer state to avoid negative effects on subsequent processes such as the packaging process. Also, metal contamination removal processes are newly provided in some cases. These lead to lower productivity, etc.

Metal impurities and particularly copper (Cu), iron (Fe), gold (Au), and sodium (Na), which are mobile ions having high diffusion rates in silicon, cause crystal defects by precipitating in the silicon wafer, form adhesion nuclei for particles at the silicon wafer surface, etc. Further, such metal impurities may reduce the performance of the semiconductor device by forming a deep electrical state in the silicon wafer, reducing the insulative properties by entering into the silicon oxide films formed in the silicon wafer surface, etc.

Various methods to remove such metal impurities have been proposed.

For example, cleaning of the silicon wafer surface using a chemical liquid (HPM (Hydrochloric acid Hydrogen Peroxide Mix) cleaning) in which HCl (hydrochloric acid), H₂O₂ (hydrogen peroxide), and H₂O (purified water) are mixed is known as a method to remove the metal impurities. However, although metal impurities appearing in the silicon wafer surface layer can be removed using wet cleaning, the metal impurities diffused into the silicon wafer cannot be removed. Moreover, enormous capital investments such as increasing the number of processes, regular contamination control, etc., are necessary.

Gettering methods to trap metal impurities also are known.

Known gettering methods include so-called extrinsic gettering (EG) and intrinsic gettering (IG).

In such cases, gettering sites are provided in regions of the silicon wafer distal to the active layers of the semiconductor device.

For example, in extrinsic gettering methods, regions of polysilicon, highly concentrated phosphorous (P), etc., are formed in the back surface of the silicon wafer; and gettering sites are formed utilizing strain and stress with the silicon. In such a case, methods called back side damage (BSD), polysilicon back seal (PBS), or phosphorous gettering are used.

In intrinsic gettering methods, the gettering sites are formed by precipitating the oxygen in the silicon wafer only in the silicon wafer interior. For example, the gettering sites are formed by inducing crystal defects by forming oxygen precipitates such as SiOₓ in the substantially central region of the silicon wafer interior.

In recent years, the need has arisen to ensure the flexural strength of the semiconductor device due to thinner films of the semiconductor device. Therefore, the processing of the silicon wafer back surface is transitioning from surface roughening using a wafer polishing method (where it is said that a rougher surface provides better gettering effects) to mirror finishing using a dry polishing method; and problems occur in which the effects of extrinsic gettering methods utilizing the strain and stress with the silicon cannot be realized.

There is a risk that the circuit pattern and the like of the substrate used in the semiconductor apparatus may become metal contamination sources. Therefore, there is a risk that the metal contamination in the back-end processes and the metal contamination from the circuit pattern and the like of the substrate usable in the semiconductor apparatus cannot be prevented even in the case where the metal impurities are removed by cleaning the silicon wafer.

In such a case, special processing becomes necessary to deliberately provide the gettering sites in the back surface of the mirror-finished silicon wafer to realize the effects of the extrinsic gettering method; and there is a risk that the number of processes may increase and the productivity may decrease.

Moreover, because it is necessary to form crystal defects in the silicon wafer interior in intrinsic gettering methods, there are cases where it may be said that such a method is undesirable from the viewpoint of the quality of the semiconductor device, etc.

Therefore, there is a need to develop technology other than gettering methods to suppress the effects of the metal contamination.

Embodiments will now be illustrated with reference to the drawings. Similar components in the drawings are marked with like reference numerals, and a detailed description is omitted as appropriate.

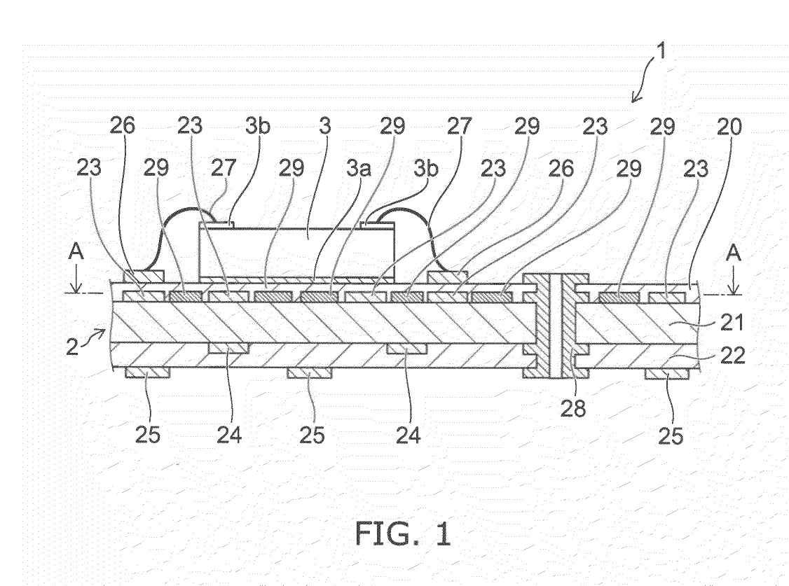

FIG. 1 is a schematic partially enlarged view illustrating the semiconductor apparatus according to this embodiment.

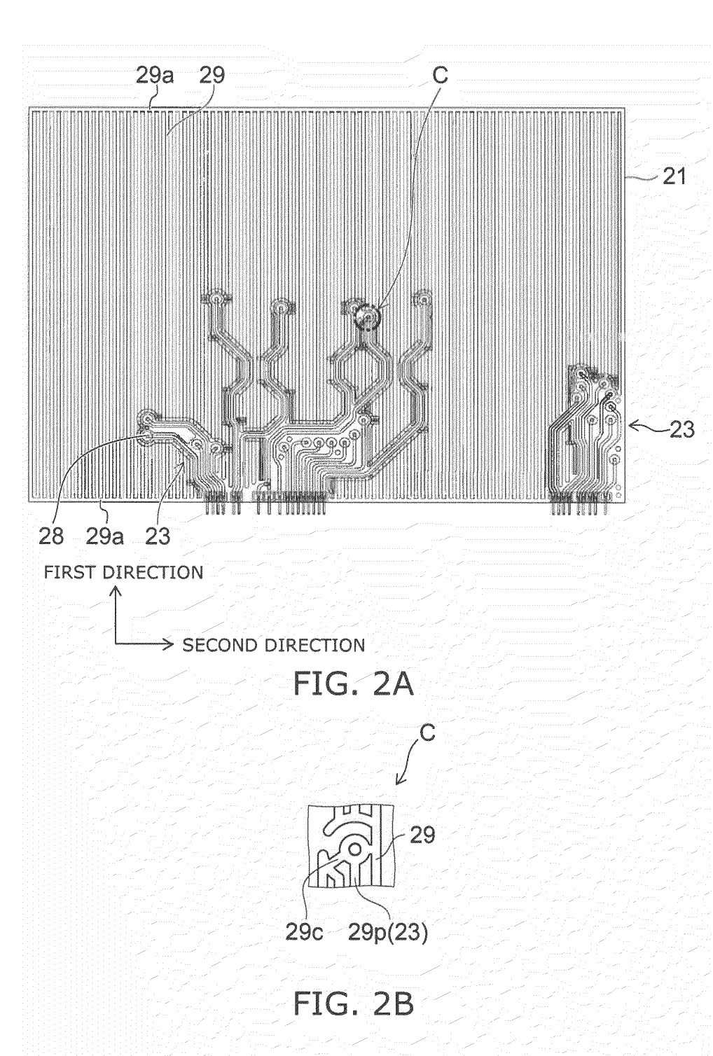

FIGS. 2A and 2B are fragmentary views along A-A of FIG. 1. FIG. 2A is a schematic view illustrating the potential unit; and FIG. 2B is an enlarged schematic view of portion C of FIG. 2A.

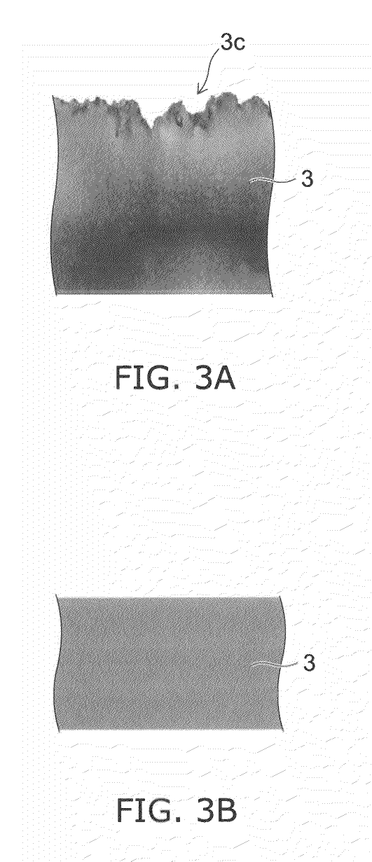

FIGS. 3A and 3B are schematic cross-sectional views illustrating properties of the back surface of the semiconductor device. FIG. 3A is a schematic cross-sectional view illustrating the case where surface roughening is performed; and FIG. 3B is a schematic cross-sectional view illustrating the case where mirror finishing is performed.

As illustrated in FIG. 1, a semiconductor apparatus 1 includes a substrate 2 and a semiconductor device 3 (a first semiconductor device) provided in the substrate 2.

The substrate 2 may be a stacked substrate provided by stacking multiple insulating layers 20, 21, and 22. In other words, the substrate 2 may be a substrate including the insulating layer 20 (a first insulating layer), the insulating layer 21 (a second insulating layer) provided by stacking on the insulating layer 20, and the insulating layer 22 provided by stacking on the insulating layer 21.

The substrate 2 may be, for example, an organic stacked substrate having an organic material such as glass epoxy as the main body or an inorganic stacked substrate having a ceramic such as aluminum oxide, an inorganic material such as glass, etc., as the main body. The substrate 2 may be a so-called rigid substrate or a flexible substrate.

Circuit patterns 23, 24, and 25 may be provided in insulating layers 20, 21, and 22. In such a case, the circuit patterns 23 and 24 are provided as inner-layer circuits; and the circuit pattern 25 is provided as an outer-layer circuit.

The circuit patterns 23, 24, and 25 may be formed from, for example, a conductor such as copper (Cu), aluminum (Al), tungsten (W), and molybdenum (Mo). The number of the insulating layers and the circuit pattern layers are not limited to those illustrated and may be modified appropriately. Here, a power source voltage, a grounding voltage, data, or a command may be applied to the interconnects of the circuit pattern 23, 24, and 25 from the outside.

The semiconductor device 3 is bonded to one major surface of the insulating layer 20 via a bonding layer 3a. In other words, the semiconductor device 3 is provided on the side of the insulating layer 20 opposite to the insulating layer 21 side. A terminal 3b of the semiconductor device 3 is electrically connected to a bonding pad 26 provided in the periphery of the semiconductor device 3 via a bonding wire 27. The bonding pad 26 is electrically connected to the circuit pattern 23.

The bonding layer 3a may be formed by, for example, adhering a bonding agent to the back surface of the semiconductor device 3 in a film-like configuration and using this in the B-stage state or by adhering a so-called die attachment film to the back surface of the semiconductor device 3.

Although the case is illustrated where the semiconductor device 3 is electrically connected to the circuit pattern 23 via the bonding wire 27, this is not limited thereto. In such a case, the semiconductor device 3 can be electrically connected to the circuit pattern 23 by a so-called face-down bonding method. For example, a flip chip method may be used in which solder bumps are formed on the terminals of the semiconductor device 3 and the semiconductor device 3 is electrically connected to the electrodes of the circuit pattern 23 via the solder bumps; or a connection method may be used in which a conductive bonding agent is coated onto protruding electrodes provided on the semiconductor device 3 and bonded to the electrodes of the circuit pattern 23, etc.

Through-hole vias 28 may be provided to pierce the insulating layers 20, 21, and 22 at prescribed locations. The circuit patterns 23, 24, and 25 provided in the insulating layers 20, 21, and 22 may be electrically connected appropriately by the through-hole vias 28. Vias such as blind via holes and buried holes may be provided to provide connections between only designated insulating layers.

The substrate 2 may appropriately include passive devices such as resistors, condensers, and coils and active devices such as transistors, diodes, etc.

Here, in the case where the back surface of the semiconductor device 3 undergoes surface roughening as illustrated in FIG. 3A, gettering sites 3c are formed in the back surface of the semiconductor device 3 utilizing the strain and stress with the silicon. Therefore, because metal impurities can be trapped by the gettering sites 3c, the metal contamination in the back-end processes and the metal contamination from the circuit pattern 23 and the like of the substrate 2 usable in the semiconductor apparatus 1 can be prevented.

However, due to thinner films of the semiconductor device 3 of recent years, breakage starting at the unevenness of the gettering sites 3c occurs more easily as the thickness of the semiconductor device 3 becomes thinner. Therefore, as illustrated in FIG. 3B, planarizing is being performed by performing mirror finishing of the back surface of the semiconductor device 3 due to the need to ensure the flexural strength, etc. In such a case, the gettering sites 3c utilizing the strain and stress with the silicon are substantially not formed in the back surface of the semiconductor device 3. Even in the case where the mirror finishing is performed, the unevenness is not completely removed from the back surface of the semiconductor device 3. In such a case, it can be discriminated whether or not mirror finishing has been performed because the unevenness is not formed in the back surface of the semiconductor device 3 when viewed at the same magnification as seen when comparing FIG. 3A and FIG. 3B. Although the gettering sites can be formed by inducing crystal defects by forming oxygen precipitates in the interior of the semiconductor device 3, it is favorable for the crystal defects not to be provided in the interior of the semiconductor device 3 from the viewpoint of the quality of the semiconductor device 3, etc.

In other words, considering the thinner films of the semiconductor device 3, etc., of recent years, it is favorable for the metal contamination to be suppressed using technology other than gettering methods.

Therefore, according to knowledge obtained by the inventors, the defect rate of the semiconductor device due to the metal contamination can be suppressed by providing a potential unit having some potential in the inner layer provided directly under the semiconductor device 3 of the substrate 2.

For example, multiple potential units 29 having line configurations may be provided between the insulating layer 20 and the insulating layer 21. Then, some potential may be applied to the potential unit 29. For example, as illustrated in FIGS. 2A and 2B, two end portions of each of the potential units 29 having the line configuration extending in the first direction may be connected to connection units 29a extending in the second direction to electrically connect the potential units 29 having line configurations to each other. Some potential can be applied to the potential unit 29 by connecting at least one selected from the potential unit 29 and the connection unit 29a having the line configurations to ground, a power source, etc. Although the case is illustrated where the potential unit 29 has a straight line configuration, this is not limited thereto. For example, the configuration may include any curve.

The circuit pattern 23 and the potential unit 29 are formed in the same layer. As a result, the potential unit 29 can be formed with suppressing to increase the number of manufacturing processes.

The installation location of the potential unit 29 according to this example is portion C illustrated in FIG. 2A. In portion C as illustrated in FIG. 2B, the end portion of a conductor 29p of the circuit pattern 23 to which a potential is applied is connected to the potential unit 29 by a connection unit 29c. Thus, a potential can be applied to the potential unit 29 with suppressing to increase the number of circuit patterns and with suppressing to increase the complexity of the circuit pattern by utilizing the potential of the circuit pattern 23. The connection unit 29c also is formed in the same layer as the circuit pattern 23 and the potential unit 29. As a result, the circuit pattern 23 is connected to the potential unit 29 by the connection unit 29c in the same layer; and an increase of the number of the interconnect layers can be prevented.

The potential unit 29 and the connection unit 29a may be formed from, for example, a conductor such as copper (Cu), aluminum (Al), tungsten (W), and molybdenum (Mo). However, this is not limited to the illustrated materials and may be modified appropriately. In the case where the potential unit 29 and the circuit pattern 23 are formed from the same material, the productivity can be increased because the potential unit 29 and the circuit pattern 23 can be formed simultaneously. For example, the potential unit 29 and the circuit pattern 23 can be formed simultaneously using subtractive methods, additive methods, etc. However, the potential unit 29 and the circuit pattern 23 may be formed individually.

By using the potential unit 29 having the line configuration in such a case, the potential unit 29 having the line configuration can be provided easily between the circuit pattern 23 even in the case where an elaborate circuit pattern 23 is formed. In other words, it is easy to provide the potential unit 29 also in the regions where the circuit pattern 23 is formed. Therefore, it is easy to provide the potential unit 29 in substantially the entire region of the inner layer provided directly under the semiconductor device 3. Further, by forming the potential unit 29 in the line configuration, it is possible to provide a substantially constant circuit pattern density and stably form the interconnects of the circuit pattern.

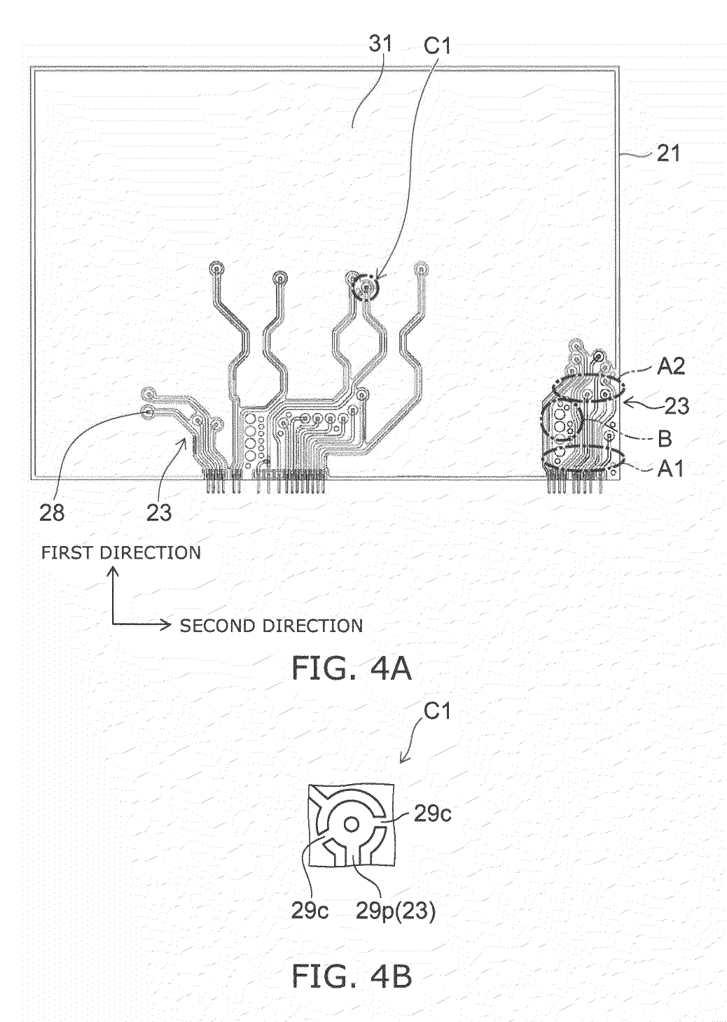

FIGS. 4A and 4B are schematic views illustrating the potential unit according to one other embodiment. FIG. 4A is a schematic view illustrating the potential unit; and FIG. 4B is an enlarged schematic view of portion C1 of FIG. 4A.

In the case illustrated in FIGS. 4A and 4B, a potential unit 31 provided between the insulating layer 20 and the insulating layer 21 has a planar configuration. Some potential is applied to the potential unit 31. For example, some potential is applied to the potential unit 31 having the planar configuration by connecting the potential unit 31 to ground, a power source, etc.

The installation location of the potential unit 31 according to this example is portion C1 illustrated in FIG. 4A. In portion C1 as illustrated in FIG. 4B, the end portion of the conductor 29p of the circuit pattern 23 to which a potential is applied is connected to the potential unit 31 by the connection unit 29c. Thus, a potential can be applied to the potential unit 31 with suppressing to increase the number of the circuit patterns and with suppressing to increase the complexity of the circuit pattern by utilizing the potential of the circuit pattern 23.

The potential unit 31 may be formed from, for example, a conductor such as copper (Cu), aluminum (Al), tungsten (W), and molybdenum (Mo). However, this is not limited to the illustrated materials and may be modified appropriately. In the case where the potential unit 31 and the circuit pattern 23 are formed from the same material, the productivity can be increased because the potential unit 31 and the circuit pattern 23 can be formed simultaneously. For example, the potential unit 31 and the circuit pattern 23 can be formed simultaneously using subtractive methods, additive methods, etc. However, the potential unit 31 and the circuit pattern 23 may be formed individually.

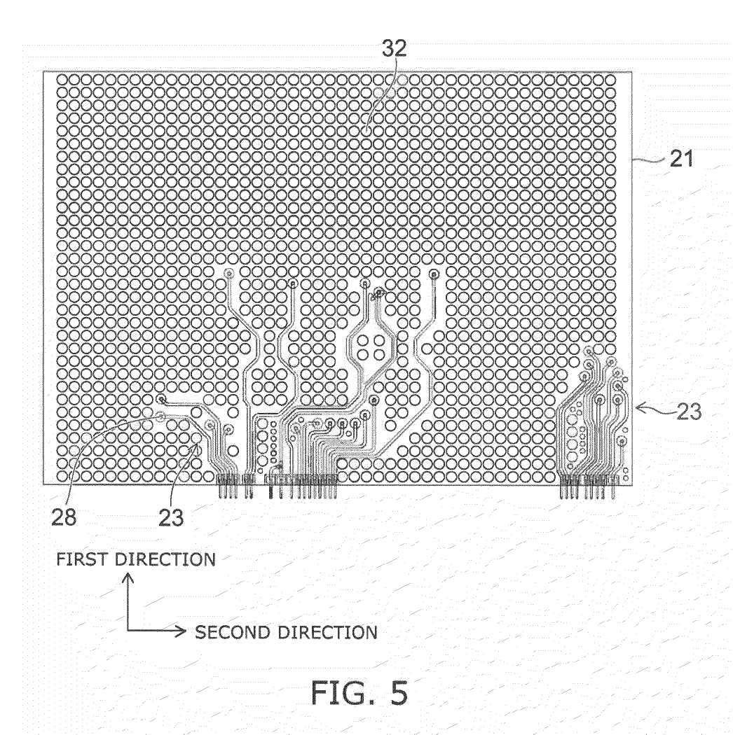

FIG. 5 is a schematic view illustrating the potential unit according to a comparative example.

In the case illustrated in FIG. 5, multiple separated potential units 32 provided between the insulating layer 20 and the insulating layer 21 are used. Then, some potential is applied to the potential units 32. For example, some potential is applied to the potential units 32 by connecting ground, a power source, etc., to each of the separated potential units 32 by a not-illustrated circuit pattern and the like. Although the potential units 32 are illustrated with circular configurations, this is not limited thereto. The configuration of the potential units 32 may be modified appropriately. In such a case, the configuration of the potential units 32 may be an equilateral triangular configuration, a square configuration, or a regular hexagonal configuration to fill in the plane.

The potential units 32 may be formed from, for example, a conductor such as copper (Cu), aluminum (Al), tungsten (W), and molybdenum (Mo). However, this is not limited to the illustrated materials and may be modified appropriately. In the case where the potential units 32 and the circuit pattern 23 are formed from the same material, the productivity can be increased because the potential units 32 and the circuit pattern 23 can be formed simultaneously. For example, the potential units 32 and the circuit pattern 23 can be formed simultaneously using subtractive methods, additive methods, etc. However, the potential units 32 and the circuit pattern 23 may be formed individually.

The configuration of the potential unit is not limited to those described above and may be modified appropriately. For example, the potential unit having the line configuration may be formed in an intersecting lattice configuration; the line width of the potential unit having the line configuration may change; the multiple separated potential units may be linked, etc.

Effects in the case where the potential unit is provided will now be described.

Table 1 illustrates the effects in the case where the potential unit is provided.

“No potential” in Table 1 is the case where the potential unit is not connected to ground, a power source, etc.

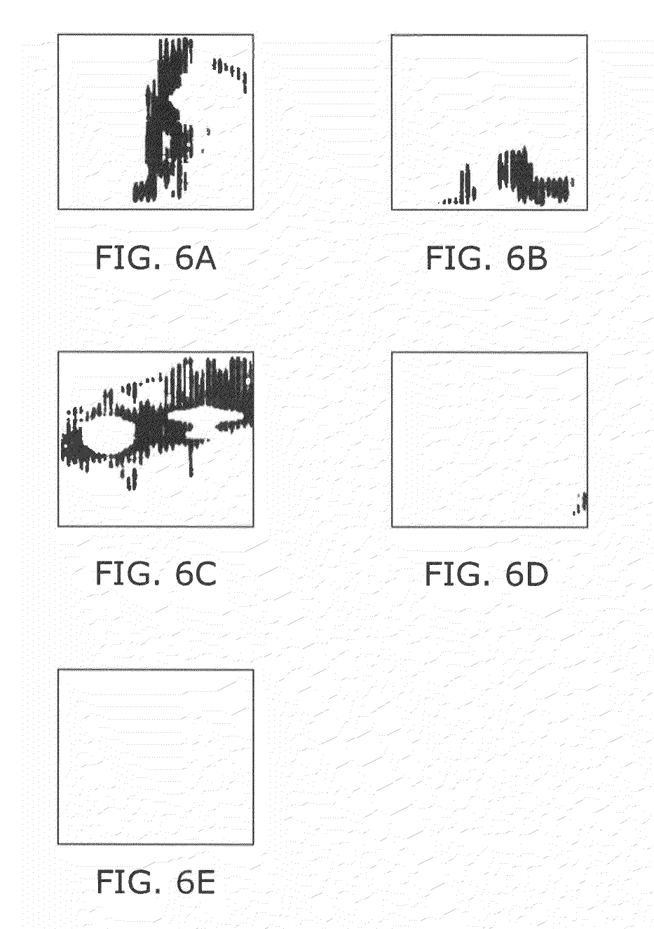

FIGS. 6A to 6E schematically illustrate fail bit maps (FMBs) for those illustrated in Table 1.

For example, in the case where the semiconductor device 3 is a semiconductor memory device, the fail bit map is a map illustrating whether or not the design value is output from the memory cells of the semiconductor device 3 as Pass/Fail when inspection information is input to the memory cells. One semiconductor memory device has several mega to several giga memory cells; and the Pass/Fail information is mapped in combination with the positions of the memory cells in the device. Then, the discrepancy regions and the like can be identified by illustrating the fail bit map in XY coordinates and by performing analysis by an analysis apparatus, an analyst, etc. The fail bit maps illustrated in FIGS. 6A to 6E are fail bit maps in which one semiconductor device 3 is selected from multiple measured semiconductor devices 3. The stacking position of the semiconductor device 3, i.e., the semiconductor memory device, is directly on the substrate 2. That is, in the case where multiple semiconductor devices are stacked, this is the semiconductor device of the lowermost layer. In the case illustrated in FIGS. 6A to 6E, the dark-colored portions are the discrepancy regions (the Fail regions).

TABLE 1

| | SAMPLE NUMBER | | | | |
|---|---|---|---|---|---|
| | 1 | 2 | 3 | 4 | 5 |
| CONFIGURATION | FIG. 5 | FIGS. 4A | FIGS. 2A | FIGS. 4A | FIGS. 2A |
| OF | | AND 4B | AND 2B | AND 4B | AND 2B |
| POTENTIAL UNIT | | | | | |
| POTENTIAL | NO | NO | NO | GROUNDING | GROUNDING |
| | POTENTIAL | POTENTIAL | POTENTIAL | POTENTIAL | POTENTIAL |
| DEFECT | 9% | 46% | 38% | 5% | 0% |
| RATE | | | | | |
| FAIL BIT | FIG. 6A | FIG. 6B | FIG. 6C | FIG. 6D | FIG. 6E |
| MAP | | | | | |

Sample number 1 of Table 1 is the case where the potential units 32 illustrated in FIG. 5 are provided. In other words, this is the case where the potential units 32 having the multiple separated circular configurations are provided. However, this is the case where the potential units 32 have no potential and are not connected to ground, a power source, etc.

In such a case, discrepancy regions having striped configurations occur in the central portion of FIG. 6A. The number of the measured samples was less than 200 and the proportion of defective parts (the defect rate) was 9%. Herein, “defective part” refers to the case where a constant number of defective memory cells occur in one semiconductor device 3. In the case of a NAND flash memory in which memory cells are multiply aggregated in blocks, “defective part” refers to the case where a constant number of defective blocks occur.

Sample number 2 of Table 1 is the case where the potential unit 31 illustrated in FIGS. 4A and 4B is provided. In other words, this is the case where the potential unit 31 having the planar configuration is provided. However, the potential unit 31 has no potential and is not connected to ground, a power source, etc.

In such a case, discrepancy regions occur in the lower portion of FIG. 6B. The number of the measured samples was the same as that of sample number 1; and the proportion of defective parts (the defect rate) was 46%.

Sample number 3 of Table 1 is the case where the potential unit 29 illustrated in FIGS. 2A and 2B is provided. In other words, this is the case where the potential units 29 having the multiple line configurations and the connection units 29a provided at the two end portions of the potential units 29 are provided. However, this is the case where the potential unit 29 has no potential and is not connected to ground, a power source, etc.

In such a case, the discrepancy regions cover a wide range in the upper portion of FIG. 6C. The number of the measured samples was the same as that of sample number 1; and the proportion of defective parts (the defect rate) was 38%.

It can be seen from sample numbers 2 and 3 that the defect rate increases as more of the non-grounded potential unit 29 exists under the semiconductor memory device. In such a case, it can be said that there is a high possibility that metal diffuses from the potential unit 29 to become a metal contamination source.

Sample number 4 of Table 1 is the case where the potential unit 31 illustrated in FIGS. 4A and 4B is provided. In other words, this is the case where the potential unit 31 having the planar configuration is provided. However, this is the case where the potential unit 31 has the grounding potential by being grounded.

In such a case, discrepancy regions occur in the lower right portion of FIG. 6D. The number of the measured samples was the same as that of sample number 1; and the proportion of defective parts (the defect rate) was 5%.

In such a case, as illustrated in FIGS. 4A and 4B, it is difficult to provide the potential unit 31 having the planar configuration in the lower right portion of the insulating layer 21 where the circuit pattern 23 is dense. Therefore, it can be conjectured that the effect of suppressing the metal contamination was less in portion B interposed between portions A1 and A2; and the defective memory cells caused by the metal contamination occurred in the semiconductor device 3 provided directly on portion B.

On the other hand, it can be seen that the effect of suppressing the metal contamination was realized in the portion where the potential unit 31 is provided; and the occurrence of the metal contamination in the semiconductor device 3 provided directly thereon was suppressed.

In other words, at least a portion of the potential unit faces the semiconductor device 3. Restated, it is sufficient for the potential unit to be provided in at least a portion that faces the semiconductor device 3.

Sample number 5 of Table 1 is the case where the potential unit 29 illustrated in FIGS. 2A and 2B is provided. In other words, this is the case where the potential units 29 having the multiple line configurations and the connection units 29a provided at the two end portions of the potential units 29 are provided. However, this is the case where the potential unit 29 has the grounding potential by being grounded.

In such a case, as illustrated in FIG. 6E, substantially no discrepancy regions occurred. In such a case, the number of the measured samples was the same as that of sample number 1; and the proportion of defective parts (the defect rate) was 0%.

As described above, by using the potential unit 29 having the line configuration, the potential unit 29 having the line configuration can be provided easily between the circuit pattern 23 even in the case where an elaborate circuit pattern 23 is formed. Therefore, it is easy to provide the potential unit 29 in substantially the entire region of the inner layer provided directly under the semiconductor device 3.

As a result, the effect of suppressing the metal contamination can be realized in the entire region of the inner layer provided directly under the semiconductor device 3; and the occurrence of the metal contamination in the semiconductor device 3 provided directly thereon can be suppressed.

Although sample number 4 and sample number 5 of Table 1 are cases where the potential unit has the grounding potential by being grounded, this is not limited thereto. According to knowledge obtained by the inventors, the effect of suppressing the metal contamination can be realized by applying some potential to the potential unit. For example, some potential may be applied to the potential unit by connecting the potential unit to a power source and the like.

In other words, it is sufficient for the potential unit to be connected to ground or a power source.

In the case where the thickness of the semiconductor device 3 is relatively thick, applications are possible in combination with a gettering method. For example, gettering sites may be formed in the back surface of the semiconductor device 3 by surface roughening; and applications are possible in combination with an extrinsic gettering method to trap the metal impurities by utilizing the strain and stress with the silicon. Also, the gettering sites may be formed by inducing crystal defects in the interior of the semiconductor device 3; and applications are possible in combination with an intrinsic gettering method to trap the metal impurities by the crystal defects. In other words, gettering sites may be further provided in at least one selected from the end portion of the semiconductor device 3 on the insulating layer 20 side and the interior of the semiconductor device 3.

Further, in the case where semiconductor devices are multiply stacked on the substrate 2 using the substrate 2 according to this embodiment, the gettering sites are formed in the back surface of the semiconductor device 3 of the lowermost layer; and the breakage starting at the unevenness is prevented by this device being slightly thick. Then, for the semiconductor devices (the second semiconductor devices) other than that of the lowermost layer, mirror finishing is performed on the back surfaces; and the thicknesses of these devices are thin.

Thus, the defect rate caused by the metal contamination can be suppressed; and the thickness of the device portion of the semiconductor apparatus 1 can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

For example, the configurations, dimensions, material qualities, numbers, dispositions, etc., of the components included in the semiconductor apparatus 1 are not limited to those illustrated and may be modified appropriately.

What is claimed is:

1. A semiconductor apparatus, comprising:
a substrate including a first insulating layer and a second insulating layer stacked with the first insulating layer;
a first semiconductor device provided on a side of the first insulating layer opposite to the second insulating layer side,
a circuit pattern provided between the first insulating layer and the second insulating layer; and
a potential unit provided between the first insulating layer and the second insulating layer,
the potential unit being connected to ground or a power source electrically.

2. The apparatus according to claim 1, wherein at least a portion of the potential unit faces the first semiconductor device.

3. The apparatus according to claim 1, wherein
the potential unit is formed in a same layer as the circuit pattern.

4. The apparatus according to claim 1, wherein the potential unit has a planar configuration.

5. The apparatus according to claim 1, wherein the potential unit has a line configuration.

6. The apparatus according to claim 1, wherein the potential unit has a straight line configuration.

7. The apparatus according to claim 1, wherein the potential unit has a configuration including any curve.

8. The apparatus according to claim 1, wherein the potential unit has a lattice configuration.

9. The apparatus according to claim 1, wherein the potential unit has a line configuration having a changed line width.

10. The apparatus according to claim 1, wherein the potential unit is formed by linking a plurality of separated portions.

11. The apparatus according to claim 1, wherein the potential unit is connected to a grounded portion of the circuit pattern or to a portion of the circuit pattern connected to a power source.

12. The apparatus according to claim 1, comprising a connection unit connecting the potential unit to the circuit pattern.

13. The apparatus according to claim 12, wherein
the potential unit has a line configuration extending in a first direction, and
the connection unit has a line configuration extending in a second direction intersecting the first direction.

14. The apparatus according to claim 1, wherein the potential unit is formed from a same material as the circuit pattern.

15. The apparatus according to claim 1, wherein the potential unit is provided in a region of the circuit pattern.

16. The apparatus according to claim 1, wherein the potential unit is formed from at least one selected from the group consisting of copper (Cu), aluminum (Al), tungsten (W), and molybdenum (Mo).

17. The apparatus according to claim 1, wherein an end portion of the first semiconductor device on the first insulating layer side is mirror-finished.

18. The apparatus according to claim 1, wherein a gettering site is provided in at least one selected from an end portion of the first semiconductor device on the first insulating layer side and an interior of the first semiconductor device.

19. The apparatus according to claim 18, further comprising a second semiconductor device provided on an end portion of the first semiconductor device on a side opposite to the first insulating layer side,
an end portion of the second semiconductor device on the first semiconductor device side being mirror-finished.

20. The apparatus according to claim 19, wherein a thickness of the first semiconductor device is thicker than a thickness of the second semiconductor device.
